(19) United States
(12) Patent Application Publication
(10) Pub. No.: US 2011/0105336 A1
(43) Pub. Date: May 5, 2011

(54) RARE EARTH ELEMENT OXIDE SUPERCONDUCTIVE WIRE MATERIAL AND METHOD OF PRODUCING THE SAME

(75) Inventors: Yasuo TAKAHASHI, Tokyo (JP); Masateru YOSHIZUMI, Tokyo (JP); Teruo IZUMI, Tokyo (JP)

(73) Assignee: International Superconductivity Technology Center, The Juridical Foundation, Tokyo (JP)

(21) Appl. No.: 12/777,686

(22) Filed: May 11, 2010

(30) Foreign Application Priority Data
Oct. 29, 2009 (JP) 2009-249172
Oct. 29, 2009 (JP) 2009-249173

(51) Int. Cl. H01B 12/02; H01L 39/24

(52) U.S. Cl. 505/230; 505/434; 427/62; 174/125.1

(57) ABSTRACT

The present invention relates to a rare earth element oxide superconductive wire material improved in orientation by forming the bed layer by the MOD method. In the superconductive wire material (10) produced by forming a MOD-CZO layer (2), an IBS-GZO (3), an IBAD-MgO layer (4), a LMO layer (5), a PLD-CeO₂ layer (6) and a PLD-GdBCO superconductive layer (8) in this order on an electropolished substrate (1) in an oxygen atmosphere, the CeO₂ layer has a value of Δφ=4.2 degrees, which is almost the same as in the case of using a mechanically polished substrate, and the GdBCO super conductive layer has a value of Ic=243 A (Jc=up to 5 MA/cm²), which is almost the same as in the case of using a mechanically polished substrate.

### CROSS REFERENCE TO RELATED APPLICATIONS

This application is entitled to claim the benefit of Japanese Patent Application No. 2009-249172, filed on Oct. 29, 2009, and Japanese Patent Application No. 2009-249173, filed on Oct. 29, 2009, the disclosures of which, including the specifications, drawings and abstracts, are incorporated herein by reference in their entirety.

### TECHNICAL FIELD

The present invention relates to improvement of a rare earth element oxide superconductive wire material useful for superconductive magnets, superconductive cables, power devices and so on, and a method of producing the wire material.

### BACKGROUND ART

A rare earth element oxide superconductive wire material each generally has a structure in which at least one or a plurality of biaxial-oriented oxide layers are formed on a metal substrate, and in which an oxide superconductive layer and then a stabilizing layer are laminated on these oxide layers, the stabilizing layer serving to protect the surface of the superconductive layer and improve the electrical contact of the superconductive layer, and also serving as a protective circuit when the superconductive layer is over-energized.

In this case, it is known that the critical current characteristics of a superconductive wire material depended on the in-plane orientation of the superconductive layer and are influenced heavily by the in-plane orientation and surface smoothness of an oriented metal substrate, which is to be the base, and a buffer layer.

A crystal system of rare earth element oxide superconductors, such as YBa₂Cu₃O_{7-δ} (hereinafter referred to as “YBCO”) superconductor material is an orthorhombic system, in which the three sides along the x axis, y axis and z axis have varying lengths and in which the angles between three sides of a unit cell also vary slightly, so that this crystal system is more likely to form twin crystals. Therefore, a slight shift in angle causes these superconductive materials to generate twin crystal grain boundaries, leading to deteriorated energizing characteristics.

Therefore, in order to optimize the characteristics of a material in respect to these energizing characteristics, it is required not only to make CuO planes uniform in the crystal, but also to make the in-plane crystal orientations uniform. Therefore, these rare earth element oxide superconductors have far more difficulty in making these materials into wires than Bi-based oxide superconductors.

A method of making the rare earth element superconductor into wire while improving the in-plane crystal orientation of the superconductor and making uniform the in-plane azimuths of crystals is on the same basis as a method of producing a thin film. Specifically, a buffer layer improved in in-plane orientation and azimuth is formed on a tape-like metal substrate and the crystal lattice of this buffer layer is used as a template to thereby improve the in-plane orientation and azimuth of the crystals in the superconductive layer.

At present, various studies have been made as to these rare earth element oxide superconductors in various production processes and various biaxial-oriented composite substrates are known in which an in-plane oriented buffer layer is formed on a tape-like metal substrate. Since the critical current characteristics of a superconductive layer formed on a buffer layer are heavily influenced by the surface smoothness of the buffer layer beneath the superconductive layer as mentioned above, there is a problem as to how to make a buffer layer having a smooth surface.

A method according to the Ion Beam Assisted Deposition (IBAD) method is currently known as one method of forming a buffer layer exhibiting the highest critical current characteristics in a superconductor provided with a rare earth element oxide superconductive layer on a substrate with a buffer layer therebetween. In this method, particles generated from a target are deposited on a polycrystalline and nonmagnetic Ni-based tape (for example, Hastelloy) having high strength by the ion beam sputtering or RF sputtering method while this Ni-based substrate is irradiated with ions from a direction forming a fixed angle with the normal line of this Ni-based substrate to form a buffer layer (CeO₂, Y₂O₃, YSZ: yttria stabilized zirconia) or a buffer layer having a double-layer structure (YSZ or Rx₂Zr₂O₇/CeO₂ or Y₂O₃ and so on, where Rx represents Y, Nd, Sm, Gd, Ei, Yb, Ho, Tm, Dy, Ce, La or Er) which have a fine crystal particle diameter and high orientation and therefore limit a reaction with an element constituting the superconductor, and a CeO film is then formed on the buffer layer by the PLD (Pulsed Laser Deposition) method. A YBCO layer or the like is formed on the resulting IBAD substrate by the PLD method or CVD (Chemical Vapor Deposition)method to produce a superconductive wire material (see, for example, Patent Literatures 1 and 2).

A composite substrate provided with an oriented MgO buffer layer (hereinafter referred to as “IBAD-MgO”) formed on a metal substrate by the above IBAD method has recently attracted remarkable attention as the composite substrate for rare earth element oxide superconductive wire material because a crystalline film is obtained at a high rate and the composite substrate is obtained at lower cost.

It is known that the IBAD-MgO film allows high-production rate because excellent biaxial orientation is obtained in a film thickness range as thin as 10 nm or less, and, on the contrary, the smoothness of a substrate used for film formation has an influence on the biaxial orientation of the IBAD-MgO layer. Thus, a process in which the surface of the metal substrate is abraded by mechanical processing has been carried out so far. For example, a metal substrate provided with a smooth surface which is mechanically polished to satisfy Ra≦2 nm is used.

In order to improve the orientation of the IBAD-MgO film, on the other hand, studies have been made as to a method in which a buffer layer which is to be the base layer (bed layer) for the IBAD-MgO film is formed on a metal substrate and an IBAD-MgO layer is formed on this bed layer. This bed layer also has the ability to prevent the diffusion of the structural elements of the metal substrate.

A method in which an amorphous layer is used as the bed layer for the MgO layer in the above IBAD method is known. In this method, a buffer layer made of a first thin film having a rock salt structure and biaxial orientation is formed on a metal substrate having a smooth amorphous surface and, using this buffer layer as a template, a second film made of a superconductive layer is formed on the buffer layer. Specifically, an in-plane oriented MgO (100) layer is formed on a substrate provided with a Si₃N₄ or SiO₂ amorphous layer having a smooth surface by the IBAD method. It has been reported that by using Hastelloy having a smooth surface as the metal substrate and by forming an amorphous layer, an IBAD-MgO layer and a YBCO substrate on Hastelloy, the Jc value of the YBCO layer can be improved. The amorphous layer is formed by treating the surface of a Ni alloy such as Hastelloy by laser processing, ion etching, high-speed mechanical processing, vapor deposition and ion implantation (see, for example, Patent Literature 3).

Also, a method in which an oxide layer having a rock salt structure is used as the bed layer for the MgO layer formed by the IBAD method is known. This structure is provided with a first buffer layer including a polycrystalline oxide disposed on a substrate, a biaxial-oriented second buffer layer directly disposed on this first buffer layer and including IBAD-MgO, IBAD-CeO₂, IBAD-(RE)₂O₃ (where (RE) is a rare earth element), and a superconductive layer disposed on this second buffer layer. Specifically, a protective layer including CeO₂ and YSZ and formed by the PLD method, a first buffer layer including an oxide such as MgO and NiO having a rock salt structure and formed by the sputtering method, PLD method or vapor deposition method, and a second buffer layer including MgO, YSZ, CeO₂ and so on, and formed by the IBAD method are laminated in this order on a Ni-based alloy substrate such as Hastelloy, and a YBCO layer and so on, are further formed thereon to thereby improve the biaxial orientation of the superconductive layer on the biaxially oriented second buffer layer (see, for example, Patent Literature 4).

On the other hand, a method in which an Al₂O₃/Y₂O₃ or Gd₂Zr₂O₇ buffer layer formed by vapor deposition using, for example, the sputtering method as the bed layer formed for the MgO layer by the IBAD method is also known.

### CITATION LIST

### Patent Literature

PTL 1: Japanese Patent Application Laid-Open No.HEI4-329867
PTL 2: Japanese Patent Application Laid-Open No.HEI4-331795

### Non Patent Literature

PTL 3: U.S. Pat. No. 6,190,752 B1
PTL 4: U.S. Pat. No. 7,071,149 B2

### SUMMARY OF INVENTION

### Technical Problem

Although a very flat surface can be obtained in a metal substrate having a smooth surface abraded by mechanical processing used to form the IBAD layer as mentioned above, this mechanically polished metal substrate has a problem concerning defects caused by local polishing failures and also has a cost problem. Also, this mechanically polished metal substrate has the problem that the bed layer vapor-deposited by a vapor phase method such as the sputtering method requires an expensive film-forming apparatus for forming a buffer layer which is a cause of increased cost.

In view of the above, it is necessary to form a bed layer for an IBAD layer having a rock salt structure such as MgO at low cost and to improve the surface smoothness of the bed layer, thereby further improving the orientation of the IBAD layer. Therefore, it is demanded of the bed layer to have a more smooth surface without using mechanical polishing or vapor deposition method.

It is an object of the present invention to provide a rare earth element oxide superconductive wire material having excellent superconductivity by improving the surface smoothness of the bed layer through formation of a bed layer by the MOD (Metal-Organic Decomposition) method in order to further improve the orientation of the IBAD layer without using any high-cost method such as mechanical polishing and vapor deposition method and also to provide a method of producing the rare earth element oxide superconductive wire material.

### Solution to Problem

The above object of the present invention is attained by an embodiment of a rare earth element oxide superconductive wire material according to the present invention, in which a first buffer layer and a rare earth element oxide superconductive layer are laminated in order on a substrate, the first buffer layer including an amorphous layer or a microcrystal layer formed by the MOD method.

In addition, according to another embodiment of the rare earth element oxide superconductive wire material of the present invention, in an oxide superconductive wire material placing a rare earth element oxide superconductive layer on a substrate via a plurality of oxide buffer layers, the buffer layers include at least a first buffer layer formed on the substrate by the MOD method and a second buffer layer formed on the first buffer layer by the IBAD method, and the rare earth element oxide superconductive layer is placed on the second buffer layer. This rare earth element oxide superconductive wire material can be made using an oxide superconductive wire material, by, for example, placing a rare earth element oxide superconductive layer on a substrate via a plurality of oxide buffer layers, by including a first buffer layer formed on the substrate by a MOD method and a second buffer layer formed on the first buffer layer by an IBAD method via a template layer in the buffer layers, and by forming the rare earth element oxide superconductive layer on the second buffer layer via the template layer.

According to an embodiment of a rare earth element oxide superconductive wire material of the present invention, a first buffer layer, a second buffer layer and a rare earth element oxide superconductive layer are laminated in order on a substrate, the first buffer layer including an amorphous layer or a microcrystal layer formed by the MOD method, the second buffer layer having a rock-salt structure and being formed by the IBAD method.

### ADVANTAGEOUS EFFECTS OF INVENTION

The first buffer layer including an amorphous layer or a microcrystal layer according to one above embodiment of the present invention can be formed with a film body calcined at a temperature equal to or higher than the thermal decomposition initiation temperature of the raw material solution applied to the surface of the substrate in an oxygen atmosphere and lower than the crystallization termination temperature of the raw material solution.

The amorphous layer or microcrystal layer constituting the first buffer layer in one above embodiment of the present invention does not strictly refer to an amorphous layer which means the state of a material such as a perfect amorphous state obtained, for example, by rapid cooling or state of a material having no long-distance order like that of crystals but a short-distance order, or microcrystals having a particle diameter of 50 nm or less, but refers to such a state (amorphous) that a wide peak appears in X-ray diffraction or the state (microcrystal layer) of the film observed before the crystallization of the amorphous film obtained before the completion of crystallization shown by the exothermic peak in the DTA-temperature curve is completed. In other words, the amorphous layer or microcrystal layer constituting the first buffer layer refers to the state observed before the crystallization is completed after the loss in weight caused by the vaporization of an organic residue in the raw material solution in the TG-temperature curve.

The thermal decomposition temperature of the raw material solution drops following the increase in the concentration of oxygen, and, therefore, an amorphous layer or microcrystal layer can be formed at a temperature lower than the temperature at which the first buffer layer is crystallized by the MOD method in an Ar atmosphere. The calcination in this case is carried out at 300 to 550° C. and preferably 350 to 500° C., although the temperature depends on the concentration of oxygen.

Also, the concentration of oxygen in an oxygen atmosphere is preferably 50 vol % or more and particularly 70 vol %.

Also, according to an embodiment of a rare earth element oxide superconductive wire material of the present invention, in an oxide superconductive wire material placing a rare earth element oxide superconductive layer on a substrate via a plurality of oxide buffer layers, the buffer layers include at least a first buffer layer formed on the substrate by the MOD method and a second buffer layer formed on the first buffer layer by the IBAD method, and the rare earth element oxide superconductive layer is placed on the second buffer layer.

This rare earth element oxide superconductive wire material can be made using an oxide superconductive wire material, by, for example, placing a rare earth element oxide superconductive layer on a substrate via a plurality of oxide buffer layers, by including a first buffer layer formed on the substrate by a MOD method and a second buffer layer formed on the first buffer layer by an IBAD method via a template layer in the buffer layers, and by forming the rare earth element oxide superconductive layer on the second buffer layer via the template layer.

Also, in each embodiment of the above invention, the first buffer layer is preferably formed by forming a [RE]-Zr—O-based oxide (where [RE] represents one or two or more types selected from the group consisting of Ce, Pr, Nd, Pm, Sm, Eu, Gd, Tb, Dy, Ho, Tm, Yb and Lu; this definition is also applicable hereinbelow), for example, [RE]₂Zr₂O₇ or YSZ on the substrate by the MOD method.

The above first buffer layer preferably has a film thickness of 20 nm or more and 300 nm or less and a surface roughness Ra of 3 nm or less, and the second buffer layer including an IBAD layer is preferably formed directly on a buffer layer having a surface roughness Ra of 3 nm or less. When the film thickness of the first buffer layer is less than 20 nm, the diffusion of the structural elements of the metal substrate is insufficiently prevented, whereas when the smoothness is further improved following the increase in film thickness (increase in the number of applications). However, this smoothness tends to be saturated when the film has a thickness above a predetermined thickness, and therefore, the thickness is designed to be 300 nm or less.

The second buffer layer including an IBAD layer is formed of MgO, GZO (Gd—Zr—O), YSZ or the like, and preferably of IBAD-MgO since a crystal film is obtained at a high rate and also at low costs as mentioned above.

The rare earth element oxide superconductive wire layer in each embodiment of the present invention includes of REBaₓCu₃O_{y} (RE is one or more elements selected from the group consisting of Y, Nd, Sm, Eu, Gd, Tb, Dy, Ho, Er, Tm and Yb, x≦2, y=6.2 to 7, hereinafter referred to as “REBCO,” the same as follows). This superconductive layer can be formed by the MOD (Metal Organic Deposition) method, PLD method, CVD method or MOCVD method (Metal Organic Chemical Vapor Deposition). Particularly, the TFA-MOD method is preferable as the film-forming method.

According to the present invention, the bed layer for the IBAD layer is formed by the MOD method and therefore, the surface smoothness can be improved. Accordingly, this enables the use of a metal substrate having low smoothness, reduction of the polishing cost and allows the temperature required for film formation to be lowered, which makes it possible to remarkably reduce the production cost by adopting the MOD method which is a non-vacuum process and also allows the IBAD layer to have the orientation equal to that of a mechanically polished metal substrate, enabling easy production of a rare earth element oxide superconductive wire material having excellent superconductivity.

### BRIEF DESCRIPTION OF DRAWINGS

FIG. 1 is a graph showing the surface roughness as a function of the number of applications to a MOD-Ce₂Zr₂O₇ (CZO) layer used in one example of a first buffer layer according to the present invention;

FIG. 2 is a graph showing the relationship between the calcination temperature of a MOD-CZO layer and the temperature difference analysis (DTA);

FIG. 3 is a graph showing the relationship between the calcination temperature of a MOD-CZO layer and a variation in weight (TG);

FIG. 4 is a view of a section vertical to the direction of the axis of a rare earth element oxide superconductive wire material in an example of the present invention;

FIG. 5 is a view of a section vertical to the direction of the axis of a rare earth element oxide superconductive wire material in another example of the present invention;

### DESCRIPTION OF EMBODIMENTS

A first buffer layer according to the present invention made of a material such as a [RE]-Zr—O-based oxide is formed by the MOD method. This MOD method is known as a method of forming a thin film on a substrate by applying a raw material solution, in which a metalorganic compound is uniformly dissolved, to a substrate and then by heating the coating film to decompose the compound. This method is a non-vacuum process and therefore enables high-speed film formation at low cost. This method is advantageously suitable to the production of a lengthy tape-like oxide superconductive wire material.

In the present invention, the calcination after the application of the raw material solution in the MOD method is carried out at a temperature equal to or higher than the thermal decomposition initiation temperature of the raw material solution and lower than the crystallization termination temperature as mentioned above. This can be confirmed by X-ray diffraction or a DTA-temperature curve.

Also, the REBaₓCu₃O_{y} (REBCO) layer according to the present invention is preferably formed by the TFA-MOD method as mentioned above. This TFA-MOD method is known as a method which does not require high-temperature heat treatment based on the MOD method involving a solid phase reaction through the formation of a carbonate of an alkali earth metal (for example, Ba) and makes it possible to obtain a superconductive film having excellent in-plane orientation. In this method, an organic acid salt containing fluorine (for example, a TFA salt: trifluoroacetate) is used as starting material and is heat-treated in a steam atmosphere to form a superconductor through the decomposition of a fluoride. In the TFA-MOD method, a liquid phase originated from HF is formed at the interface where a superconductive film is grown while HF gas is generated by the reaction between a fluorine-containing amorphous precursor obtained after the calcination of the coating film and steam to thereby form a superconductor from the interface of the substrate by epitaxial growth. It is therefore necessary to discharge the HF gas promptly from the film surface. If the HF gas is insufficiently discharged, the crystal growth rate of the superconductor is inhibited.

It is preferable to mix a metal organic acid salt solution containing one or more elements selected from Zr, Ce, Sn or Ti in the above raw material solution, whereby an oxide of BaZrO₃ and so on, can be dispersed as pinning points in the REBCO superconductor layer and particularly, the magnetic characteristics of a YBCO superconductor which has a large reduction rate of 1c value under a low magnetic field can be improved.

The REBCO superconductive layer is formed by repeating a plurality of times the processes of applying a raw material solution containing a metal element constituting the superconductor to the surface of the buffer layer and calcining the coating film, to thereby laminate each coating film so as to obtain a prescribed thickness after the crystallization heat treatment.

In the invention described above, it is preferable to use a Ni-based alloy and Ni containing one or more elements selected from W, Mo, Cr, Fe, Cu, V, Sn and Zn may be used.

The present invention will be described in more detail by way of examples.

### EXAMPLES

### Example 1

### Number of Applications of MOD Layers vs. Surface Roughness

A CZO (Ce—Zr—O) layer which has been used as the Ni—W alloy substrate barrier layer for the material of the bed layer of the IBAD layer was formed on a Hastelloy substrate by the MOD method to examine the smoothness of the CZO layer.

Using, as the metal substrate, a rolled substrate (A) which was a Hastelloy substrate of 10 mm in width and 70 μm in thickness, and an electropolished substrate (B) obtained by electropolishing a Hastelloy substrate, a naphthenic acid solution of Ce and Zr was applied to each of these substrates by the DIP coating method. Then, each substrate was continuously calcined at 500° C. in an Ar atmosphere and at 400° C. in an O₂ atmosphere in a Reel-to-Reel (RTR) continuous calcination furnace to form CZO films having different film thicknesses on the Hastelloy substrate. Then, the surface roughness (Ra) as a function of the number of applications was measured by observation using an atomic force microscope (AFM).

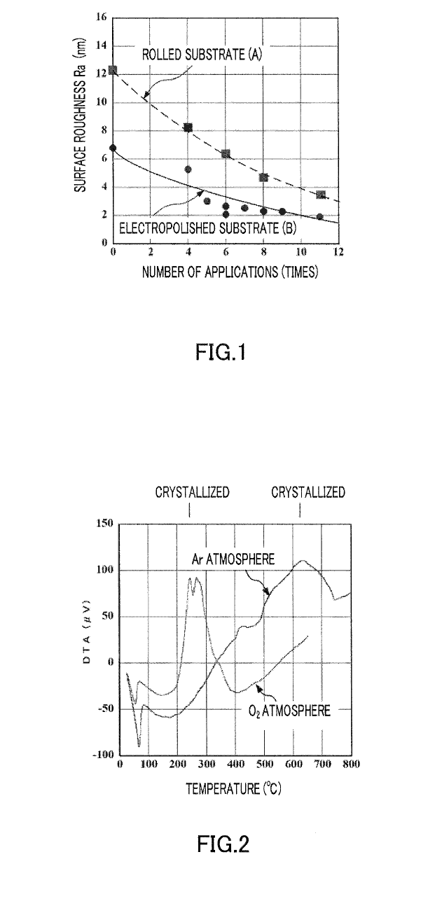

The initial surface roughnesses Ra of the rolled substrate (A) and the electropolished substrate (B) before the application were 12.3 nm and 6.5 nm, respectively. FIG. 1 shows the results of the measurement of the surface roughness (Ra) as a function of the number of applications of the MOD-CZO layer in an Ar atmosphere.

It is to be noted that substantially the same results were obtained in an O₂ atmosphere. In FIG. 1, the symbols “▪” and “” represent the actual measured values of the surface roughnesses of the rolled substrate (A) and electropolished substrate (B), respectively.

It is found from the results that the Ra value of any of the rolled substrate (A) and electropolished substrate (B) in an Ar atmosphere and O₂ atmosphere tend to decrease gradually following the increase of the number of applications of the CZO layer. In particular, in the case of the electropolished substrate (B), the Ra value drops to about 3 nm when the number of applications is about 6 to 7, showing that the electropolished substrate (B) exhibits almost the same smoothness as a mechanically polished substrate (up to 2 nm) which is currently known to exhibit excellent superconductivity.

(Influence of the Atmosphere)

Also, using a differential thermogravimetric simultaneous measuring meter to determine the influence of the calcination temperature of the MOD-CZO layer, the relationship between calcination temperature and temperature difference (difference in electromotive force of a thermocouple: μV) or weight change (TG) due to vaporization or chemical change in an Ar or O₂ atmosphere was measured.

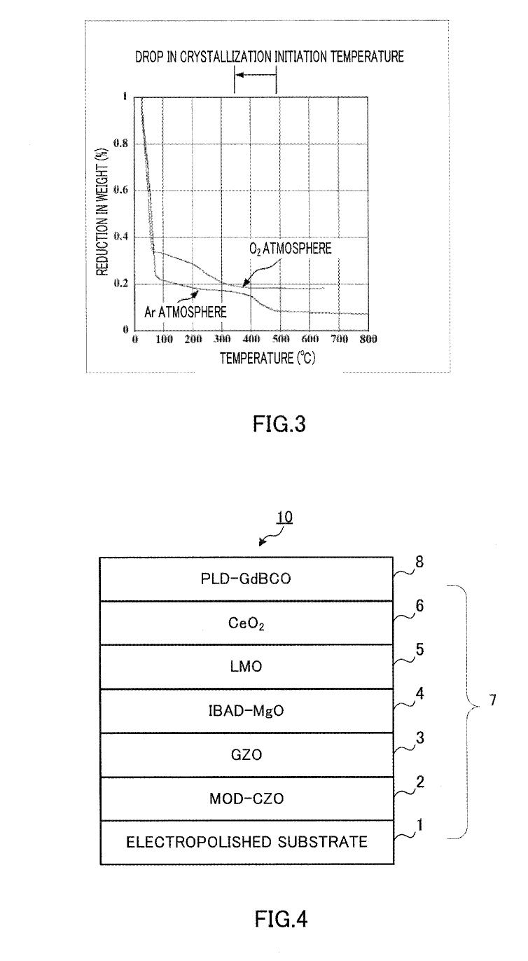

The results of the measurement are shown in FIG. 2 and FIG. 3. According to FIG. 2 and FIG. 3, while the thermal decomposition of the MOD-CZO film starts at about 400° C. and the crystallization of the MOD-CZO film starts at about 500° C. in an Ar atmosphere, the thermal decomposition terminates and the crystallization starts at about 200 to 350° C. in an O₂ atmosphere.

As mentioned above, the start/termination temperatures of the thermal decomposition of the raw material solution drop and the crystallization initiation temperature also drops following the increase in the concentration of oxygen in the atmosphere. Therefore, an amorphous layer or a microcrystal layer can be formed at a temperature lower than the temperature at which the first buffer layer is crystallized, by the MOD method, in an Ar atmosphere.

(In-Plane Texture of a CeO₂ Cap Layer)

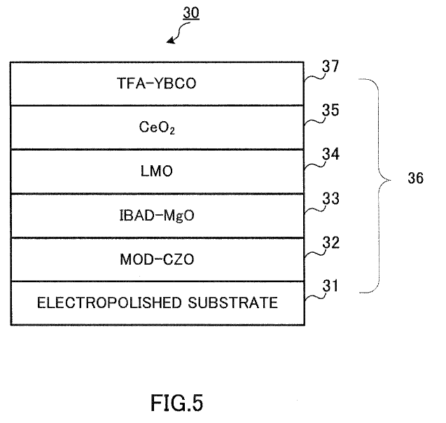

The orientation of the buffer layer was evaluated in the following manner. Specifically, as shown in FIG. 4, MOD-CZO layer 2 of about 80 nm in thickness was formed in an oxygen atmosphere and GZO (Gd₂Zr₂O₇) layer 3 of about 110 nm in thickness was formed as a template layer (for a IBAD-MgO layer), by the ion beam sputtering method (IBS), on electropolished substrate 1 having Ra of 6.5 mm. Then, IBAD-MgO layer 4 of about 5 to 10 nm in thickness was formed, LaMnO₃ (LMO) layer 5 of about 10 nm in thickness was formed as a template layer (for a CeO₂ layer) by the sputtering method, and CeO₂ layer 6 of about 0.5 μm in thickness was formed as a cap layer by the PLD method, in this order, on GZO layer 3. Then, the orientation of the CeO₂ layer was evaluated.

The in-plane orientation of CeO₂ layer 6 of this composite substrate 7 was measured based on the full width half maximum (FWHM) of X-ray diffraction (XRD), and the following result was obtained: Δφ=4.2 degrees. This value is almost the same level as that (Δφ=up to 4 degrees) obtained when a mechanically polished substrate is used.

(Characteristics of the Rebco Layer)

GdBCO superconductive layer 8 of about 0.5 μm in thickness was formed by the PLD method on the CeO₂ layer of composite substrate 7 formed in the manner described above to evaluate the Jc value in the following condition: 77 K, using the DC four-terminal method with a criterion of 1 μV/cm in a self magnetic field.

Rare earth element oxide superconductive wire material 10 produced in this manner had the structure (PLD-CeO₂/LMO/IBAD-MgO/IBS-GZO/MOD-CZO/electropolished Hastelloy substrate) as shown in FIG. 4 and GdBCO superconductive layer 8 exhibited the following Ic value: Ic=243 A (Jc=up to 5 MA/cm²). This value was almost the same level as that (Jc=5 to 6 MA/cm²) obtained when a mechanically polished Hastelloy substrate was used.

### Example 2

Using an electropolished substrate having Ra of 5 nm prepared by electropolishing a Hastelloy substrate, a MOD-CZO layer was formed on this substrate in an oxygen atmosphere in the same manner as in Example 1. After an IBAD-MgO layer and a LMO layer (template layer) were formed on this MOD-CZO layer, a CeO₂ layer was formed 0.5 μm thick on this LMO layer to produce a composite substrate.

A GdBCO superconductive layer of about 0.5 μm in thickness was formed on the CeO₂ layer of the composite substrate by the PLD method.

The in-plane orientation and Ic of the CeO₂ layer of the rare earth element oxide superconductive wire material having the structure (PLD-GdBCO/PLD-CeO₂/LMO/IBAD-MgO/MOD-CZO/electropolished substrate) were measured by the same method as in Example 1, and the following results were obtained: Δφ=6.5 degrees, and Ic=177 A.

### Example 3

As shown in FIG. 5, using electropolished substrate 31 having Ra of 5 nm prepared by electropolishing a Hastelloy substrate, MOD-CZO layer 32 was formed on this substrate in an oxygen atmosphere in the same manner as in Example 1. After IBAD-MgO layer 33 and LMO layer 34 (template layer) were formed on this MOD-CZO layer, CeO₂ layer 35 was formed 1 μm thick on this LMO layer to produce composite substrate 36.

YBCO superconductive layer 37 of about 1.3 μm in thickness was formed on CeO₂ layer 35 of composite substrate 36 by the TFA-MOD method.

The in-plane orientation and Ic of CeO₂ layer 35 of rare earth element oxide superconductive wire material 30 having the structure (MOD-YBCO/PLD-CeO₂/LMO/IBAD-MgO/MOD-CZO/electropolished substrate) were measured by the same method as in Example 1, and the following results were obtained: Δφ=4.7 degrees, and Ic=245 A.

### Example 4

Using an electropolished substrate having Ra of 5 nm prepared by electropolishing a Hastelloy substrate, a MOD-CZO layer, an IBS-GZO layer (template layer), an IBAD-MgO layer and a LMO layer (template layer) were formed in this order on this substrate in an oxygen atmosphere in the same manner as in Example 1. Then, a CeO₂ layer of 0.5 μm in thickness was formed on this LMO layer to produce a composite substrate.

Further, a GdBCO superconductive layer of about 0.5 in thickness was formed by the PLD method and a YBCO superconductive layer of about 1.4 μM in thickness was formed by the TFA-MOD method on the CeO₂ layer of the composite substrate.

The in-plane orientation of the CeO₂ layer of the rare earth element oxide superconductive wire material having structure (1) (PLD-GdBCO/PLD-CeO₂/LMO/IBAD-MgO/IBS-GZO/MOD-CZO/electropolished substrate) and structure (2) (MOD-YBCO/PLD-CeO₂/LMO/IBAD-MgO/IBS-GZO/MOD-CZO/electropolished substrate) was measured by the same method as in Example 1, and the following results were obtained: Δφ=5.6 degrees, and Ic values of Ic=246 A for structure (1) and Ic=298 A for structure (2).

### Example 5

Using an electropolished substrate having Ra of 5 nm prepared by electropolishing a Hastelloy substrate, a MOD-CZO layer, an IBS-GZO layer (template layer), an IBAD-MgO layer and a LMO layer (template layer) were formed in this order on this substrate in an oxygen atmosphere in the same manner as in Example 4. Then, a CeO₂ layer was formed 1 μm thick on this LMO layer to produce a composite substrate.

A YBCO superconductive layer of about 1.4 μm in thickness was formed on the CeO₂ layer of the composite substrate by the TFA-MOD method.

The in-plane orientation and Ic of the CeO₂ layer of the rare earth element oxide superconductive wire material having the structure (MOD-YBCO/PLD-CeO₂/LMO/IBAD-MgO/IBS-GZO/MOD-CZO/electropolished substrate) were measured by the same method as in Example 1, and the following results were obtained: Δφ=4.3 degrees, and Ic=322 A.

It is found from the above results of Examples 2 to 5 that, in the case of forming no IBS-GZO layer as the template layer for the IBAD-MgO layer in the rare earth element oxide superconductive wire material in which the MOD-CZO layer was formed as the bed layer for the IBAD-MgO layer in an oxygen atmosphere, the orientation of the CeO₂ layer and the Ic value of the PLD-GdBCO layer are slightly lower than those of a mechanically polished substrate when the film is 0.5 μm thick, but the orientation of the CeO₂ layer and the Ic value of the TFA-YBCO layer are almost equal to those of a mechanically polished substrate when the film is 1 μM thick.

It is also found, in the case of forming an IBS-GZO layer as the template layer for the IBAD-MgO layer, on the other hand, in the rare earth element oxide superconductive wire material in which the MOD-CZO layer was formed as the bed layer for the IBAD-MgO layer in an oxygen atmosphere, the orientation of the CeO₂ layer is slightly lower than that of a mechanically polished substrate, but the Ic value of the PLD-GdBCO layer is almost equal to that of a mechanically polished substrate and the Ic value of the TFA-YBCO layer is equal to or higher than that of a mechanically polished substrate.

Moreover, in the case of the CeO₂ layer of 1 μm in thickness, it has the same orientation as a mechanically polished substrate and the Ic value of the TFA-YBCO layer is equal to or higher than that of a mechanically polished substrate.

### INDUSTRIAL APPLICABILITY

Because the surface smoothness of the IBAD layer can be further improved by the present invention, an inexpensive metal substrate can be used, making it possible to easily produce a rare earth element oxide superconductive wire material having excellent superconductive characteristics at low costs. The superconductive wire material is effectively applied to superconductive magnets, superconductive cables, power devices and so on.

### REFERENCE SIGNS LIST

1, 31: Electropolished substrate
2, 32: MOD-CZO layer
3: GZO layer
4, 33: IBAD-MgO layer
5, 34: LaMnO₃ (LMO) layer
6, 35: CeO₂ layer
7, 36: Composite substrate
8: GdBCO superconductive layer
10, 30: Rare earth element oxide superconductive wire material
37: YBCO superconductive layer

1. A rare earth element oxide superconductive wire material, wherein, a first buffer layer and a rare earth element oxide superconductive layer are laminated in order on a substrate, the first buffer layer including one of an amorphous layer and a microcrystal layer formed by a metal organic deposition method.

2. A rare earth element oxide superconductive wire material, wherein, in an oxide superconductive wire material placing a rare earth element oxide superconductive layer on a substrate via a plurality of oxide buffer layers, the buffer layers include at least a first buffer layer formed on the substrate by a metal organic deposition method and a second buffer layer formed on the first buffer layer by an ion beam assisted deposition method, and the rare earth element oxide superconductive layer is placed on the second buffer layer.

3. The rare earth element oxide superconductive wire material according to claim 2, wherein the first buffer layer includes at least one of an amorphous layer and a microcrystal layer formed by a metal organic deposition method, and the second buffer layer and the rare earth element oxide superconductive layer are laminated in order on the first buffer layer.

4. The rare earth element oxide superconductive wire material according to claim 2, wherein the first buffer layer includes at least one of an amorphous layer and a microcrystal layer is formed of a film body calcined at a temperature equal to or higher than a thermal decomposition initiation temperature of a raw material solution applied to the surface of the substrate in an oxygen atmosphere and lower than a crystallization termination temperature of the raw material solution.

5. The rare earth element oxide superconductive wire material according to claim 4, wherein an oxygen concentration in the oxygen atmosphere is 50 volume percent or more.

6. The rare earth element oxide superconductive wire material according to claim 1, wherein the first buffer layer includes a [RE]-Zr—O-based oxide (where [RE] represents one or more types selected from the group consisting of Ce, Pr, Nd, Pm, Sm, Eu, Gd, Tb, Dy, Ho, Tm, Yb and Lu) or YSZ.

7. The rare earth element oxide superconductive wire material according to claim 1, wherein a film thickness in the first buffer layer is 20 nanometers or more and 300 nanometers or less.

8. The rare earth element oxide superconductive wire material according to claim 1, wherein a surface roughness Ra of the first buffer layer is 3 nanometers or less.

9. The rare earth element oxide superconductive wire material according to claim 1, wherein the second buffer layer includes MgO.

10. The rare earth element oxide superconductive wire material according to claim 1, wherein the rare earth element oxide superconductive layer includes REBaₓCu₃O_{y} (where RE is one or more elements selected from the group consisting of Y, Nd, Sm, Eu, Gd, Tb, Dy, Ho, Er, Tm and Yb, x≦2, y=6.2 to 7; this definition is also applicable hereinbelow).

11. The rare earth element oxide superconductive wire material according to claim 1, wherein the rare earth metal oxide superconductive layer comprises a film body formed by a pulsed laser deposition method, a metal organic deposition method or a metal organic chemical vapor deposition method.

12. The rare earth element oxide superconductive wire material according to claim 1, further comprising a template layer between the first buffer layer and the second buffer layer and/or between the second buffer layer and the rare earth element oxide superconductive layer.

13. The rare earth element oxide superconductive wire material according to claim 10, wherein the REBaₓCu₃O_{y} superconductive layer comprises an oxide superconductive layer in which an oxide containing one or more elements selected from the group consisting of Zr, Ce, Sn and Ti is dispersed.

14. A method of producing a rare earth element oxide superconductive wire material, the method comprising:
forming a first buffer layer including [RE]-Zr—O-based oxide or YSZ having a film thickness of 20 nanometers or more and 300 nanometers or less and a surface roughness Ra of 3 nanometers or less on a substrate by a metal organic deposition method;
forming a second buffer layer including MgO on the first buffer layer by an ion beam assisted deposition method; and
forming a REBaₓCu₃O_{y} superconductive layer on the second buffer layer by a trifluoroacetic acid-metal organic deposition method.
